(19) United States
(12) Patent Application Publication
(10) Pub. No.: US 2021/0327731 A1
(43) Pub. Date: Oct. 21, 2021

(54) MASS TRANSFER METHOD, MASS TRANSFER DEVICE AND BUFFER CARRIER

(71) Applicant: Advanced Semiconductor Engineering, Inc., Kaohsiung (TW)

(72) Inventors: Chih-Wen CHANG, Kaohsiung (TW); Yu-Ho HSU, Kaohsiung (TW); Tai-Yuan HUANG, Kaohsiung (TW); Ping-Feng YANG, Kaohsiung (TW); Fu-Ting CHANG, Kaohsiung (TW); Chin-Feng WANG, Kaohsiung (TW)

(73) Assignee: Advanced Semiconductor Engineering, Inc., Kaohsiung (TW)

(21) Appl. No.: 16/849,904

(22) Filed: Apr. 15, 2020

(51) Int. Cl. H01L 21/67; H01L 21/687; H01L 25/065

(52) U.S. Cl. CPC H01L 21/67155; H01L 25/0655; H01L 21/68714

(57) ABSTRACT

A mass transfer method, a mass transfer device and a buffer carrier are provided. The mass transfer method includes: (a) providing a plurality of electronic components disposed on a source carrier; (b) providing a buffer carrier including a plurality of adjusting cavities; and (c) transferring the electronic components from the source carrier to the buffer carrier, wherein the electronic components are placed in the adjusting cavities of the buffer carrier to adjust positions of the electronic components from shifted positions to correct positions.

### BACKGROUND

### 1. Field of the Disclosure

The present disclosure relates to mass transfer tools and a mass transfer method, and to a mass transfer device, a buffer carrier and a mass transfer method using the mass transfer device and the buffer carrier.

### 2. Description of the Related Art

As for semiconductor packages, such as panel level package (PLP), manufacturing processes typically include wafer based processing and transferring techniques. To reduce manufacturing time, it is necessary to transfer multi-dies from a singulated wafer to a substrate or a carrier. However, the singulating process and the transferring process may cause positions of the multi-dies to shift, thereby decreasing manufacturing yield.

### SUMMARY

In some embodiments, a mass transfer method includes: (a) providing a plurality of electronic components disposed on a source carrier; (b) providing a buffer carrier including a plurality of adjusting cavities; and (c) transferring the electronic components from the source carrier to the buffer carrier, wherein the electronic components are placed in the adjusting cavities of the buffer carrier to adjust positions of the electronic components from shifted positions to correct positions.

In some embodiments, a mass transfer device includes a plurality of suction pads. The suction pads are spaced apart from each other. At least one of the suction pads has a first surface and a second surface opposite to the first surface, and includes an accommodating cavity recessed from the second surface.

In some embodiments, a buffer carrier includes a main body and a plurality of adjusting cavities. The main body has an upper surface. The adjusting cavities are recessed from the upper surface of the main body. At least one of the adjusting cavities has an inner adjusting sidewall below the upper surface of the main body.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a perspective view of one or more stages of an example of a mass transfer method according to some embodiments of the present disclosure.

FIG. 2 illustrates a cross-sectional view along line X-X of FIG. 1.

FIG. 3 illustrates a perspective view of a mass transfer device according to some embodiments of the present disclosure.

FIG. 4 illustrates a cross-sectional view along line X-X of FIG. 3.

FIG. 5 illustrates a perspective view of a mass transfer device in a viewing angle opposite to FIG. 3 according to some embodiments of the present disclosure.

FIG. 6 illustrates an exploded perspective view of a suction unit according to some embodiments of the present disclosure.

FIG. 7 illustrates an exploded perspective view of a suction unit according to some embodiments of the present disclosure.

FIG. 8 illustrates a perspective view of one or more stages of an example of a mass transfer method according to some embodiments of the present disclosure.

FIG. 9 illustrates a cross-sectional view along line X-X of FIG. 8.

FIG. 10 illustrates a perspective view of a buffer carrier according to some embodiments of the present disclosure.

FIG. 11 illustrates a cross-sectional view along line Y-Y of FIG. 10.

FIG. 12 illustrates an enlarged view of an area “C” of FIG. 11.

FIG. 13 illustrates an enlarged view of an area “C” of FIG. 11 according to some embodiments of the present disclosure.

FIG. 14 illustrates a cross-sectional view of one or more stages of an example of a mass transfer method according to some embodiments of the present disclosure.

FIG. 15 illustrates an enlarged view of an area “A” of FIG. 14.

FIG. 16 illustrates a cross-sectional view of one or more stages of an example of a mass transfer method according to some embodiments of the present disclosure.

FIG. 17 illustrates an enlarged view of an area “B” of FIG. 16.

FIG. 18 illustrates a perspective view of one or more stages of an example of a mass transfer method according to some embodiments of the present disclosure.

FIG. 19 illustrates a cross-sectional view along line X-X of FIG. 18.

FIG. 20 illustrates a perspective view of one or more stages of an example of a mass transfer method according to some embodiments of the present disclosure.

FIG. 21 illustrates a cross-sectional view along line X-X of FIG. 20.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

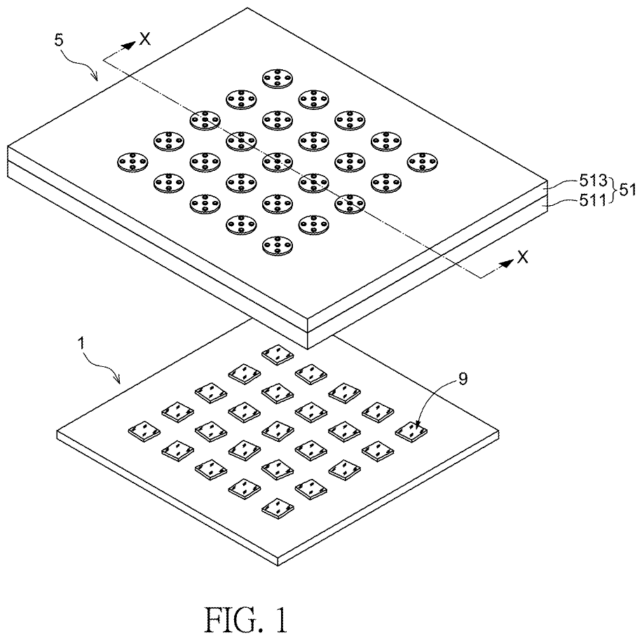

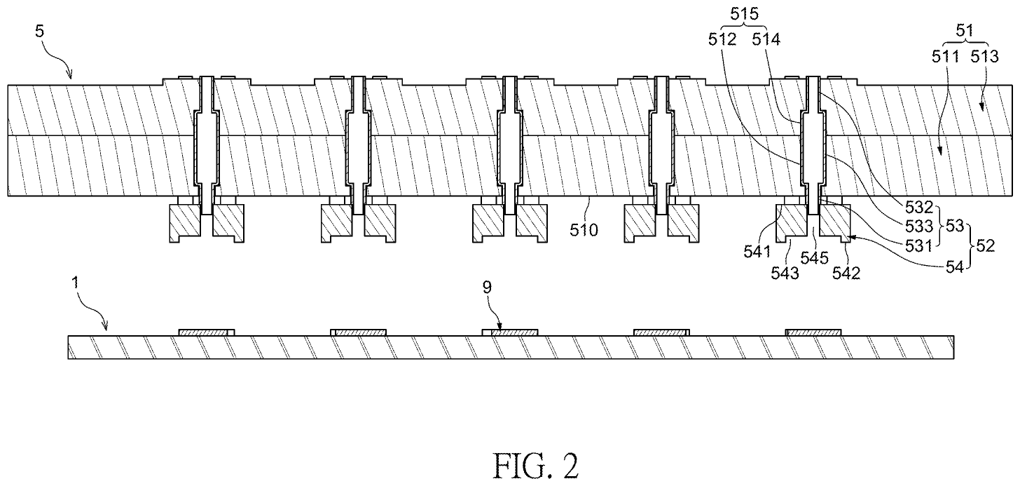

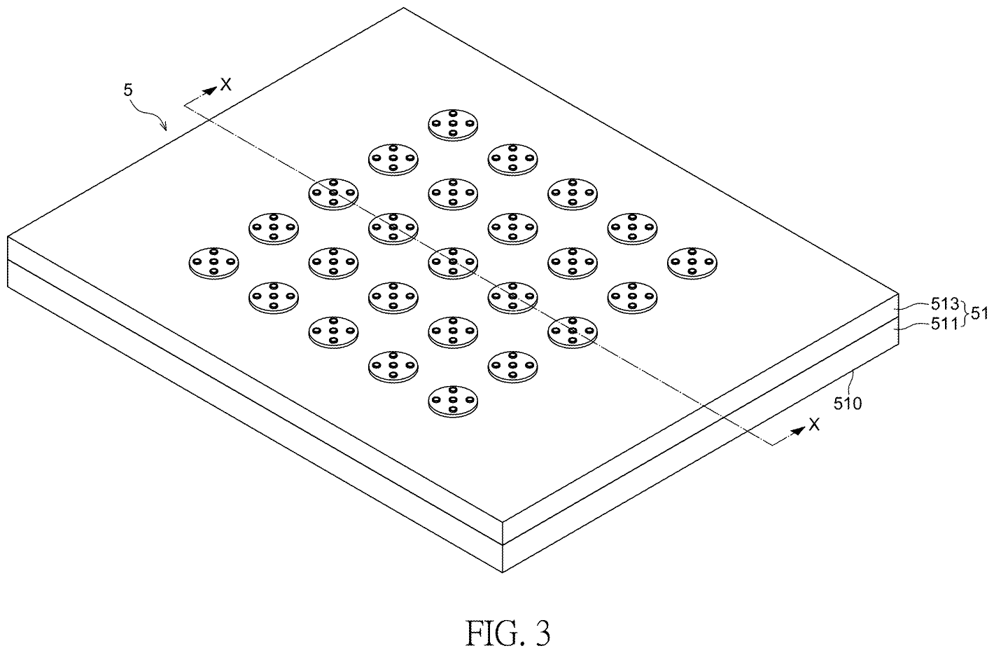

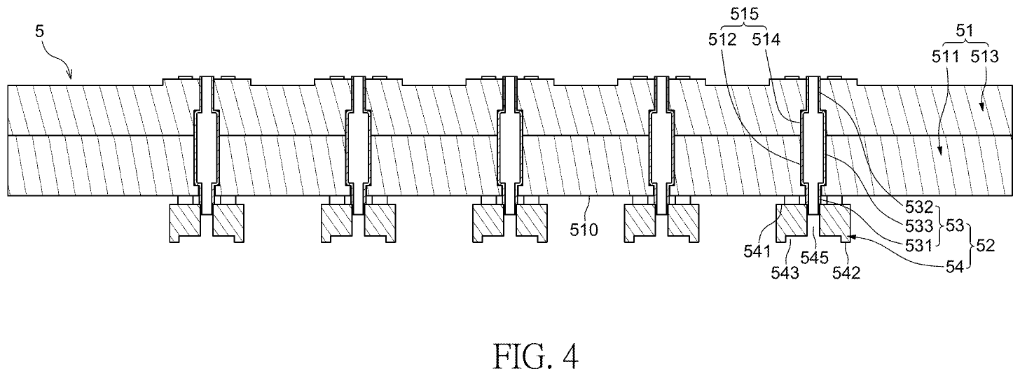

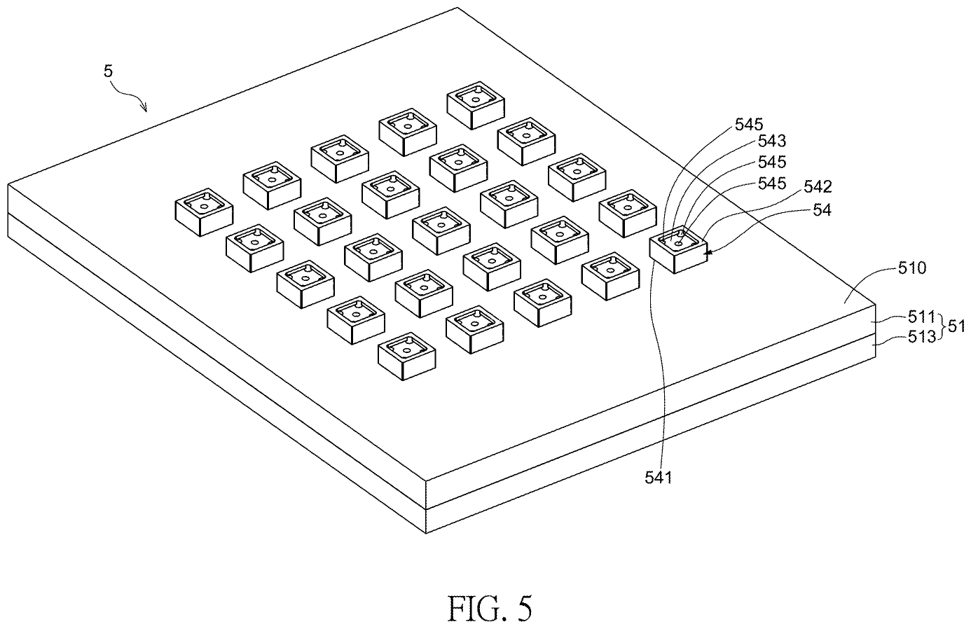

FIG. 1 through FIG. 21 illustrate a mass transfer method according to some embodiments of the present disclosure. Referring to FIG. 1 through FIG. 5, a plurality of electronic components 9 and a mass transfer device 5 are provided. FIG. 1 illustrates perspective views of the electronic components 9 and the mass transfer device 5 according to some embodiments of the present disclosure. FIG. 2 illustrates a cross-sectional view along line X-X of FIG. 1. FIG. 3 illustrates an enlarged view of the mass transfer device 5 of FIG. 1. FIG. 4 illustrates a cross-sectional view along line X-X of FIG. 3. FIG. 5 illustrates a perspective view of the mass transfer device 5 in a viewing angle opposite to FIG. 3. Each of the electronic components 9 may be, for example, a semiconductor die or a semiconductor chip. In some embodiments, the electronic components 9 may be singulated from a wafer. Further, the electronic components 9 may be disposed on a source carrier 1. The source carrier 1 may be a tpae such as dicing tape. The mass transfer device 5 is used to transfer the electronic components 9.

In some embodiments, as shown in FIG. 3 through FIG. 5, the mass transfer device 5 may include a base 51 and a plurality of suction units 52. The base 51 may define a plurality of through holes 515 extending through the base 51. In some embodiments, the base 51 may include a first base portion 511 and a second base portion 513 connected to the first base portion 511. That is, the through holes 515 extend through the first base portion 511 and the second base portion 513. In some embodiments, the first base portion 511 may define a plurality of first through holes 512 extending through the first base portion 511, and the second base portion 513 may define a plurality of second through holes 514 extending through the second base portion 513 and corresponding to the first through holes 512. Thus, one of the first through holes 512 of the first base portion 511 and the corresponding one of the second through holes 514 of the second base portion 513 may constitute one of the through holes 515.

The suction units 52 may be spaced apart from each other and connected to the base 51. Further, the suction units 52 may be used to pick and place the electronic components 9. In some embodiments, at least one or all of the suction units 52 may include at least one suction pin 53 and a suction pad 54. Thus, the mass transfer device 5 may include a plurality of suction pads 54 spaced apart from each other. The at least one suction pin 53 may be disposed in one of the through holes 515 of the base 51 and connected to a vacuum pump to generate a suction force for sucking the electronic component 9. The at least one suction pin 53 may be a hollow structure. In addition, a portion of the at least one suction pin 53 may protrude from a bottom surface 510 of the base 51.

In some embodiments, as shown in FIG. 3 and FIG. 5, at least one of the suction units 52 may include a plurality of suction pins 53 to generate a uniform suction force. Further, at least one of the suction pins 53 may include a first end portion 531, a second end portion 532 and an intermediate portion 533. A portion of the first end portion 531 may be disposed in the first through hole 512 of the first base portion 511, and another portion of the first end portion 531 may protrude from the bottom surface 510 of the base 51. The second end portion 532 is opposite to the first end portion 531 and may be disposed in the second through hole 514 of the second base portion 513. The intermediate portion 533 is between and in communication with the first end portion 531 and the second end portion 532. In some embodiments, the intermediate portion 533 may be disposed in the first through hole 512 of the first base portion 511 and the second through hole 514 of the second base portion 513. That is, a portion of the intermediate portion 533 is disposed in the first through hole 512 of the first base portion 511, and another portion of the intermediate portion 533 is disposed in the second through hole 514 of the second base portion 513. In some embodiments, a diameter of the intermediate portion 533 may be greater than a diameter of the first end portion 531 and a diameter of the second end portion 532 to prevent the suction pin 53 from leaving from the base 51 (including, for example, the first base portion 511 and the second base portion 513) due to vibration or other process factors.

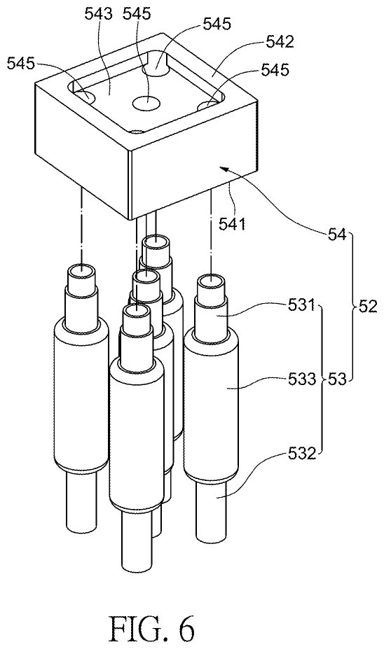

FIG. 6 illustrates an exploded perspective view of a suction unit 52 according to some embodiments of the present disclosure. Referring to FIG. 4 through FIG. 6, one of the suction pads 54 of the suction units 52 is connected to the corresponding one of the suction pins 53. In some embodiments, the suction pad 54 may be connected to the protruded portion (e.g., the protruded portion of the first end portion 531) of the suction pin 53. Further, a material of the suction pad 54 may be antistatic to prevent the electronic component 9 from being damaged by the static generated by the suction pad 54.

The suction pad 54 has a first surface 541 adjacent to the base 51 and a second surface 542 opposite to the first surface 541. In addition, the suction pad 54 may define an accommodating cavity 543 and at least one through hole 545 extending through the suction pad 54. The accommodating cavity 543 may be recessed from the second surface 542 and in communication with the through hole 545. The accommodating cavity 543 may be used to accommodate the electronic component 9. Thus, a size of the accommodating cavity 543 may be substantially equal to a size of the electronic component 9. In some embodiments, a portion of the protruded portion (e.g., the first end portion 531) of the suction pin 53 may be disposed or inserted in the through hole 545 of the suction pad 54.

In some embodiments, as shown in FIG. 5 and FIG. 6, the suction pad 54 may define a plurality of through holes 545 extending through the suction pad 54. The first end portions 531 of the suction pins 53 may be disposed in the through holes 545 of the suction pad 54 respectively. Thus, the suction pins 53 are in communication with the accommodating cavity 543.

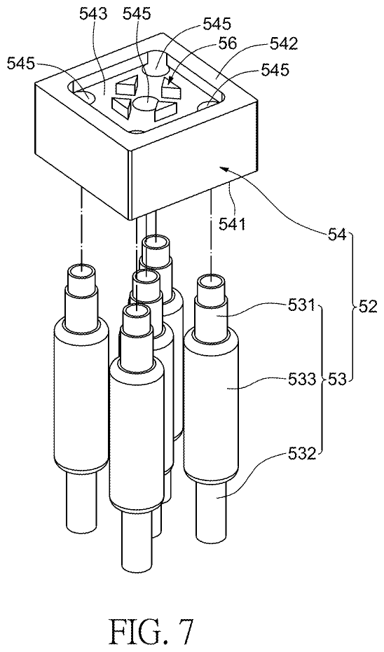

FIG. 7 illustrates an exploded perspective view of a suction unit according to some embodiments of the present disclosure. In some embodiments, as shown in FIG. 7, at least one of the suction units 52 may further include at least one elastic element 56. The elastic element 56 may be disposed in the accommodating cavity 543 of the suction pad 54. When the electronic component 9 is sucked in the accommodating cavity 543, the elastic element 56 may serve as a buffer to prevent the electronic component 9 from being broken due to an impact.

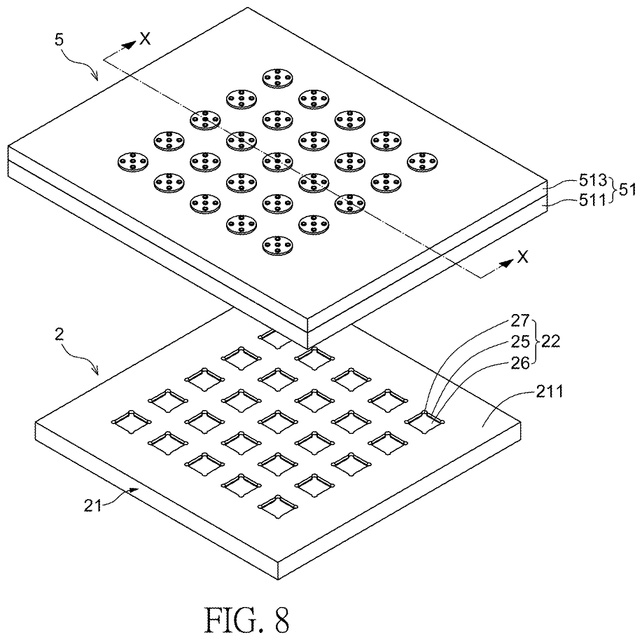

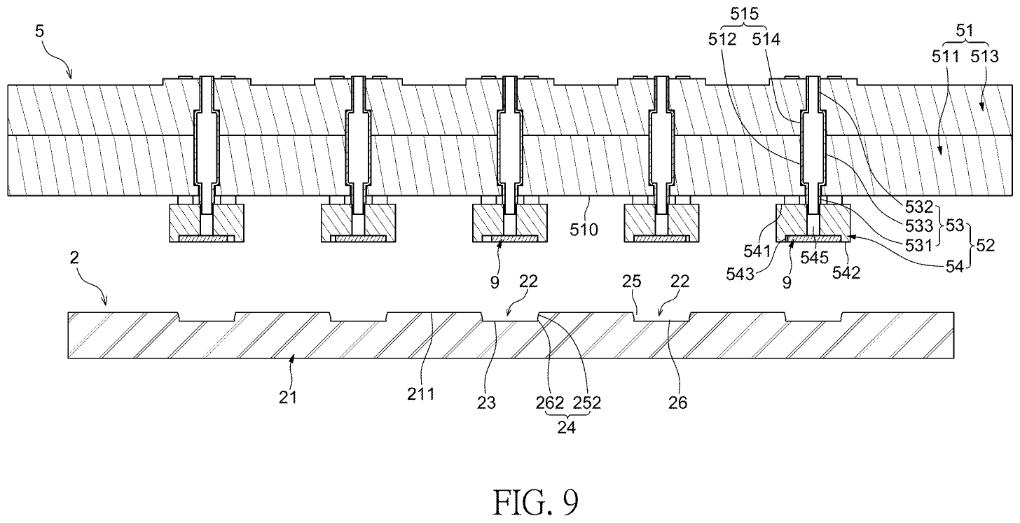

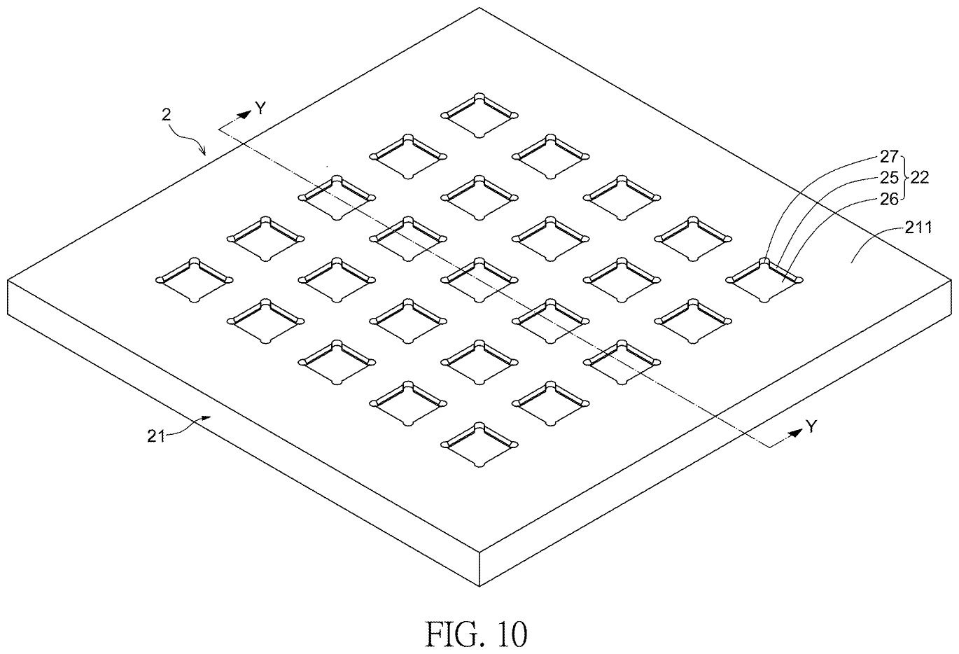

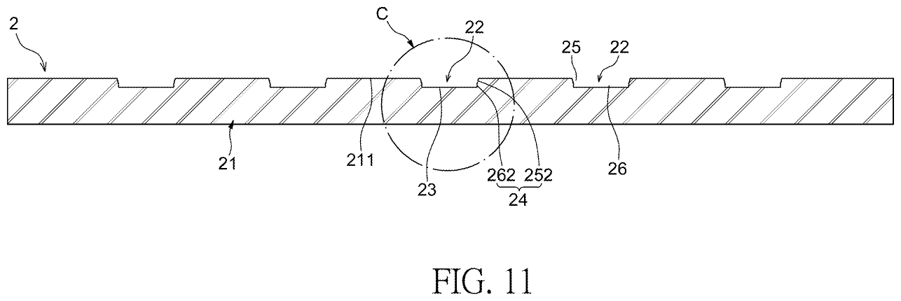

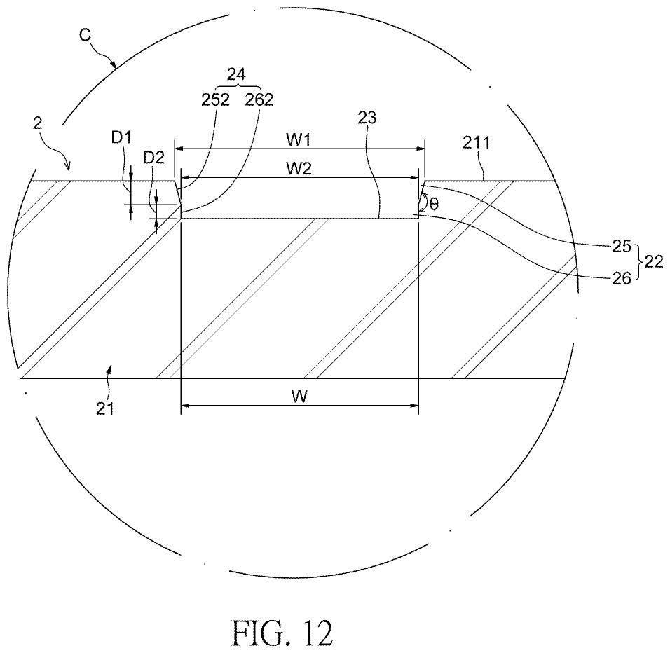

Referring to FIG. 8 through FIG. 13, a buffer carrier 2 is provided. FIG. 8 illustrates perspective views of a buffer carrier 2 and a mass transfer device 5 according to some embodiments of the present disclosure. FIG. 9 illustrates a cross-sectional view along line X-X of FIG. 8. FIG. 10 illustrates an enlarged view of the buffer carrier 2 of FIG. 8. FIG. 11 illustrates a cross-sectional view along line Y-Y of FIG. 10. FIG. 12 illustrates an enlarged view of an area “C” of FIG. 11. The buffer carrier 2 may be used to adjust positions of the electronic components 9 from shifted positions to correct positions. In some embodiments, as shown in FIG. 10 through FIG. 12, the buffer carrier 2 may include a main body 21 and a plurality of adjusting cavities 22. The main body 21 has an upper surface 211, and a material of the main body 21 may be antistatic to prevent the electronic components 9 from being damaged by the static generated by the main body 21. In some embodiments, the material of the main body 21 may be, for example, polyetheretherketone (PEEK) or ceramic.

As shown in FIG. 10 and FIG. 12, the adjusting cavities 22 may be recessed from the upper surface 211 of the main body 21. In addition, at least one of the adjusting cavities 22 may have an inner bottom surface 23 and an inner adjusting sidewall 24, and may include an upper opening 25, a lower opening 26 and at least one alignment opening 27. The inner bottom surface 23 may be, for example, a flat surface. The inner adjusting sidewall 24 is below the upper surface 211 of the main body 21 and may extend between the inner bottom surface 23 and the upper surface 211 of the main body 21. The inner adjusting sidewall 24 may be used to adjust the positions of the electronic components 9 from the shifted positions to the correct positions. In some embodiments, the inner adjusting sidewall 24 may be an inclined sidewall (e.g., an inclined sidewall 252) or a combination of the inclined sidewall (e.g., the inclined sidewall 252) and a vertical sidewall (e.g., a vertical sidewall 262).

The upper opening 25 may be recesssed from the upper surface 211 of the main body 21. In some embodiments, as shown in FIG. 11 and FIG. 12, the upper opening 25 may taper downward. That is, a size (e.g., width) of a top portion of the upper opening 25 is greater than a size (e.g., width) of a bottom portion of the upper opening 25. Meanwhile, the upper opening 25 has an inclined sidewall 252 (or a slant sidewall). In addition, the top portion of the upper opening 25 has a maximum width W1 adjacent to the upper surface 211 of the main body 21. The bottom portion of the upper opening 25 has a minimum width W2 adjacent to the lower opening 26. The lower opening 26 may be between the upper opening 25 and the inner bottom surface 23. In some embodiments, the lower opening 26 may have a vertical sidewall 262. Thus, the inclined sidewall 252 of the upper opening 25 and the vertical sidewall 262 of the lower opening 26 may constitute the inner adjusting sidewall 24. Further, an included angle θ may be between the inclined sidewall 252 of the upper opening 25 and the vertical sidewall 262 of the lower opening 26. To ensure that the electronic component 9 may quickly fall from the upper opening 25 to the lower opening 26 to complete the position adjustment, the included angle θ may be 160° to 170°. In addition, a size of the lower opening 26 may be substantially equal to a size of the electronic component 9.

To improve the accuracy of position adjustment of the electronic component 9, a size of the lower opening 26 may be slightly greater than a size of the electronic component 9. To ensure the electronic component 9 may fall into the lower opening 26 smoothly and accurately, as shown in FIG. 12, the maximum width W1 of the upper opening 25 may be greater than a width W of the lower opening 26. The minimum width W2 of the upper opening 25 may be equal to the width W of the lower opening 26 since the vertical sidewall 262 of the lower opening 26 is perpendicular to the inner bottom surface 23. A depth D1 of the upper opening 25 may be greater than a depth D2 of the lower opening 26. In some embodiments, a sum of the depth D1 of the upper opening 25 and the depth D2 of the lower opening 26 may be greater then a thickness of the electronic component 9 (FIG. 9).

As shown in FIG. 9 and FIG. 10, the alignment opening 27 may be disposed adjacent to at least one corner of the at least one of the adjusting cavities 22 to improve the alignment efficiency between the electronic components 9 and the adjusting cavities 22. In some embodiments, the alignment opening 27 may be in communication with the upper opening 25 and the lower opening 26. That is, at least a portion of the alignment opening 27 is connected to the upper opening 25 and the lower opening 26. Further, the alignment opening 27, the upper opening 25 and the lower opening 26 may be formed concurrently.

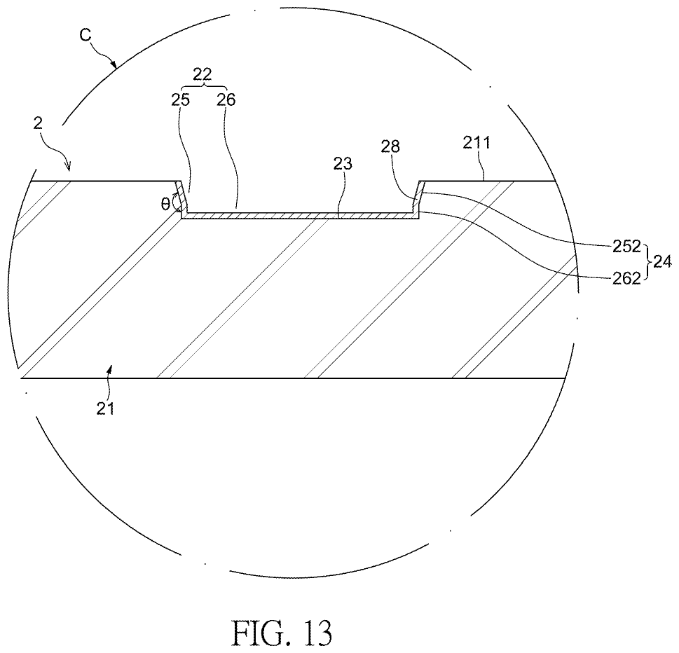

FIG. 13 illustrates an enlarged view of an area “C” of FIG. 11 according to some embodiments of the present disclosure. In some embodiments, as shown in FIG. 13, the buffer carrier 2 may further include a smooth coating 28. The smooth coating 28 may cover the inner adjusting sidewall 24 to reduce friction between the electronic component 9 (FIG. 9) and the inner adjusting sidewall 24, thereby adjusting the position of the electronic component 9 rapidly. In some embodiments, the smooth coating 28 may further cover the inner bottom surface 23. Further, a material of the smooth coating 28 may be, for example, a diamond-like carbon coating (DLCC).

Referring to FIG. 1 through FIG. 2, FIG. 8 through FIG. 9 and FIG. 14 through FIG. 17, the electronic components 9 are transferred from the source carrier 1 to the buffer carrier 2 through the mass transfer device 5. As shown in FIG. 1 through FIG. 2 and FIG. 8 through FIG. 9, the mass transfer device 5 picks up the electronic components 9 from the source carrier 1. In some embodiments, the electronic components 9 may be sucked by the suction pins 53 of the suction units 52 and attached to the suction pads 54 of the suction units 52. Further, the electronic components 9 may be sucked into the accommodating cavities 543 of the suction pads 54 through the suction pins 53 of the suction units 52.

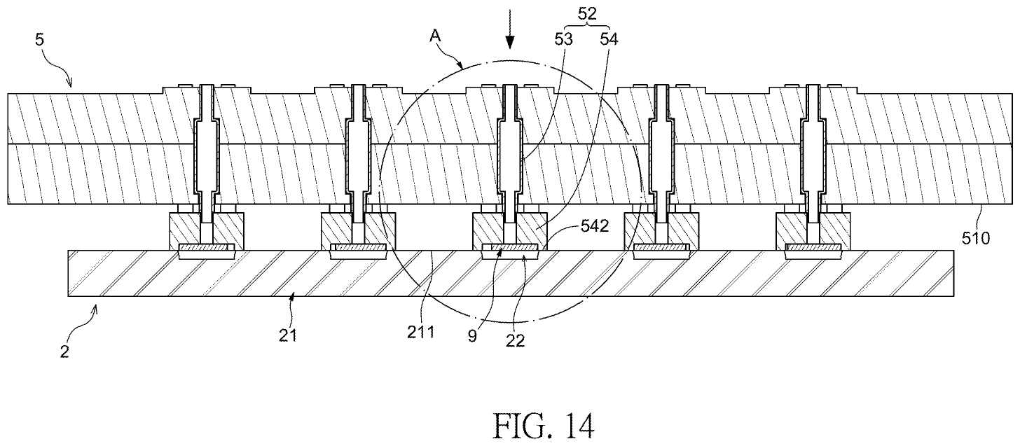

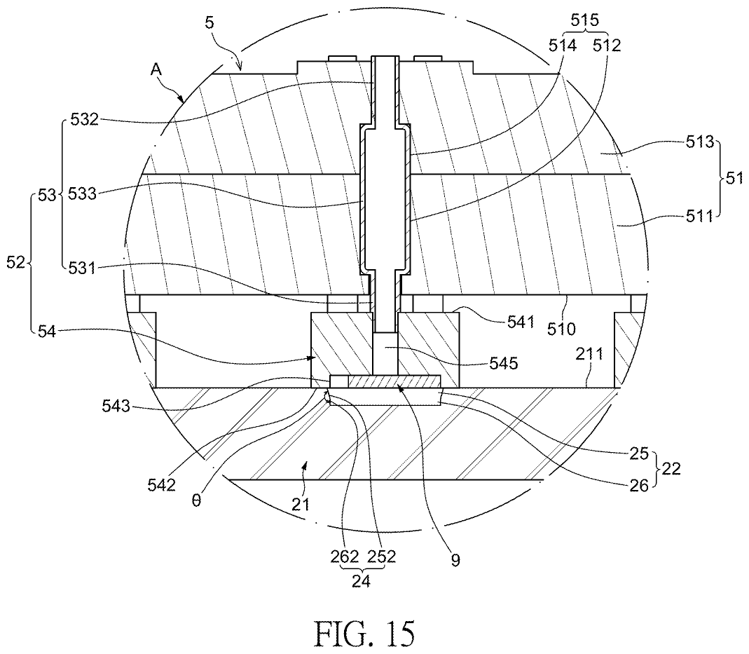

As shown in FIG. 14 through FIG. 15, wherein FIG. 15 illustrates an enlarged view of an area “A” of FIG. 14, the mass transfer device 5 is moved downward to the buffer carrier 2. The suction units 52 of the mass transfer device 5 may contact the buffer carrier 2. In some embodiments, the second surface 542 of the suction pad 54 of the suction unit 52 may contact an upper surface (i.e., the upper surface 211 of the main body 21) of the buffer carrier 2.

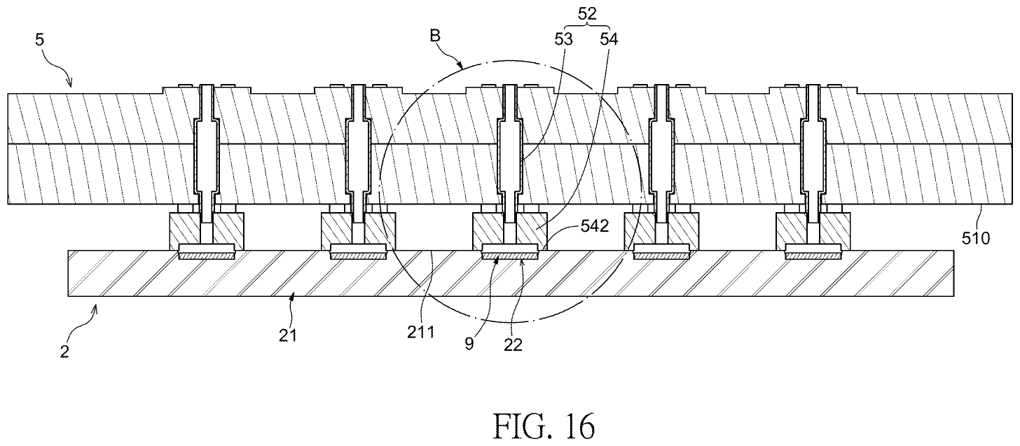

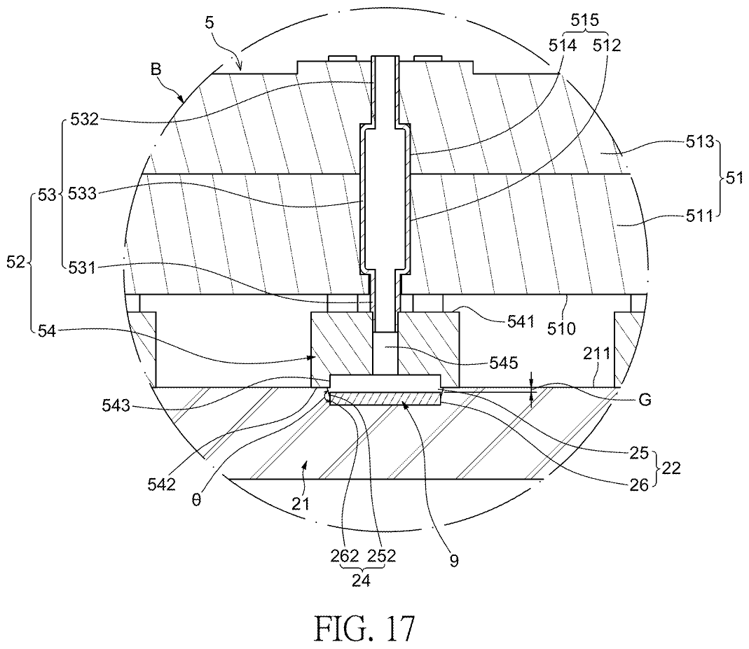

As shown in FIG. 16 through FIG. 17, wherein FIG. 17 illustrates an enlarged view of an area “B” of FIG. 16, the electronic components 9 are placed in the adjusting cavities 22 of the buffer carrier 2 through aligning with the alignment opening 27 (FIG. 10) of the at least one of the adjusting cavities 22. Meanwhile, the positions of the electronic components 9 may be adjusted form the shifted positions to the correct positions through the upper openings 25, the lower openings 26 and the inner adjusting sidewalls 24 (including, for example, the inclined sidewalls 252 of the upper openings 25 and the vertical sidewalls 262 of the lower openings 26) of the adjusting cavities 22. In some embodiments, the suction forces from the mass transfer device 5 to the electronic components 9 are released, and then, the electronic components 9 fall into the adjusting cavities 22 of the buffer carrier 2 due to gravity. When the electronic component 9 fall from the upper opening 25 to the lower opening 26, the edges of the electronic component 9 may slide on the inner adjusting sidewalls 24 (including, for example, the inclined sidewalls 252 of the upper openings 25 and the vertical sidewalls 262 of the lower openings 26). If the electronic component 9 is in a shifted position of FIG. 1, it may rotate slightly and/or move horizontally during the falling process. Then, the electronic component 9 reaches to and fits in the lower opening 26 so as to complete the position adjustment. Therefore, all of the electronic components 9 are in the correct positions. In some embodiments, a gap G may be between the electronic component 9 and the suction pad 54 of the suction unit 52. The gap G is a vertical distance between a top surface of the electronic component 9 and the second surface 542 of the suction pad 54. Alternatively, the gap G may be a vertical distance between a top surface of the electronic component 9 and the upper surface 211 of the main body 21 of the buffer carrier 2. Thus, the electronic component 9 may not protrude from the upper surface 211 of the main body 21 of the buffer carrier 2.

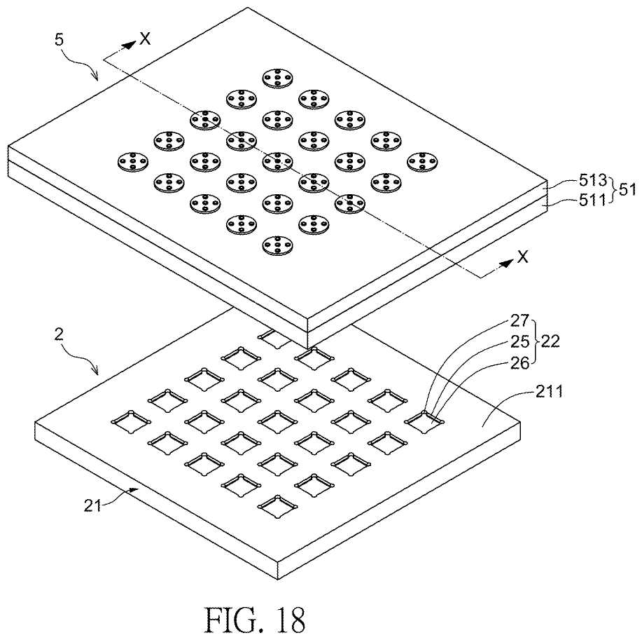

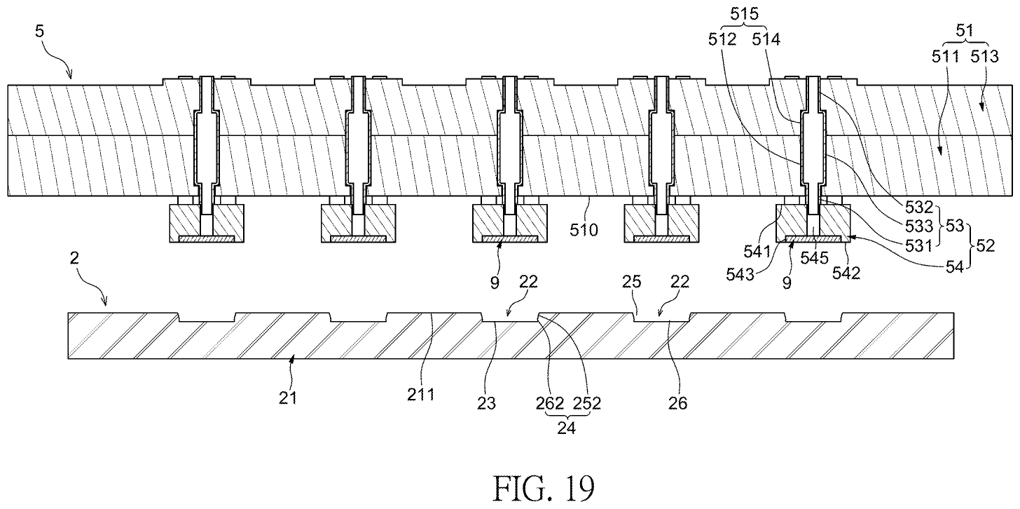

Referring to FIG. 18 through FIG. 21, the position-adjusted electronic components 9 are transferred from the buffer carrier 2 to a receiving carrier 3. The receiving carrier 3 may be, for example, a substrate. As shown in FIG. 18 and FIG. 19, wherein FIG. 19 illustrates a cross-sectional view along line X-X of FIG. 18, the mass transfer device 5 picks up the position-adjusted electronic components 9 from the buffer carrier 2. In some embodiments, the position-adjusted electronic components 9 may be sucked by the suction pins 53 of the suction units 52 and attached to the suction pads 54 of the suction units 52 again. That is, the position-adjusted electronic components 9 may be sucked into the accommodating cavities 543 of the suction pads 54 through the suction pins 53 of the suction units 52 again.

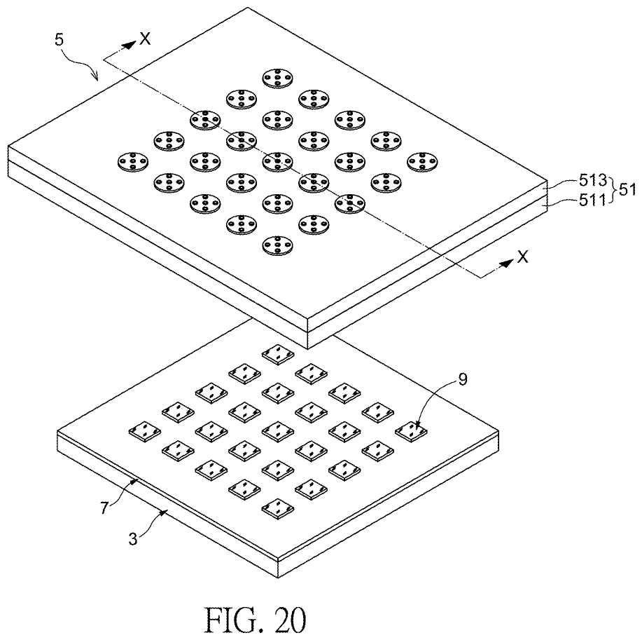

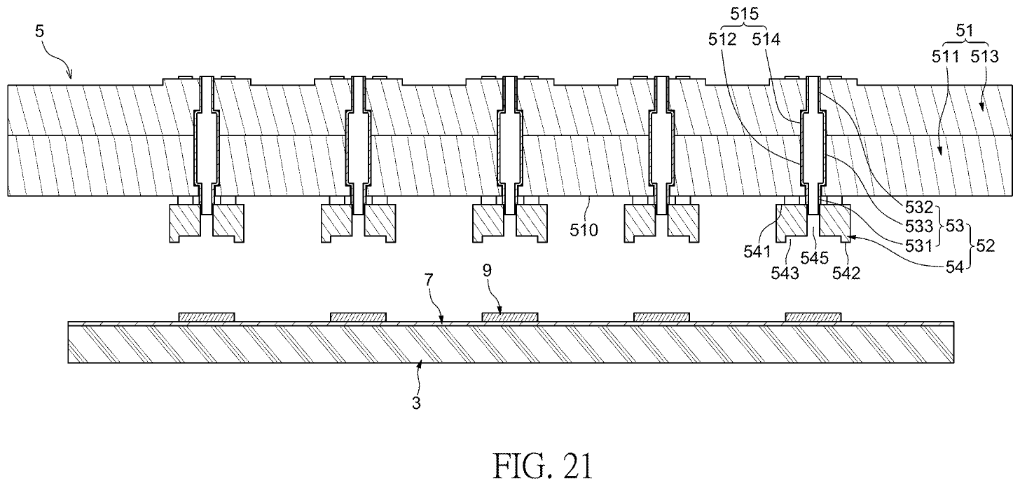

As shown in FIG. 20 and FIG. 21, wherein FIG. 21 illustrates a cross-sectional view along line X-X of FIG. 20. the mass transfer device 5 is moved to the receiving carrier 3 and places the position-adjusted electronic components 9 on the receiving carrier 3. In some embodiments, the suction forces from the mass transfer device 5 to the position-adjusted electronic components 9 are released, and then, the position-adjusted electronic components 9 fall on the receiving carrier 3 due to gravity. Since all the position-adjusted electronic components 9 are in the correct positions after mass transferring, the yield of the following manufacturing process may be significantly improved.

In some embodiments, an adhesion layer 7 may be formed or disposed on the receiving carrier 3, and the position-adjusted electronic components 9 may be attached to the receiving carrier 3 through the adhesion layer 7. Further, the adhesion layer 7 may be baked to bond the position-adjusted electronic components 9 and the receiving carrier 3 tightly.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

1. A mass transfer method, comprising:
(a) providing at least two electronic components on a source carrier;
(b) providing a buffer carrier including a plurality of cavities;
(c) transferring the at least two electronic components from the source carrier to the cavities of the buffer carrier through a mass transfer device, wherein the mass transfer device contacts an upper surface of the buffer carrier; and
(d) transferring the at least two electronic components in the cavities from the buffer carrier to a receiving carrier.

2. (canceled)

3. The method of claim 1, wherein in (b), the buffer carrier further includes a main body having an upper surface, the cavities are recessed from the upper surface of the main body, and at least one of the cavities has an inner adjusting sidewall below the upper surface of the main body; wherein in (c), the position of the electronic component is adjusted through the inner adjusting sidewall of the at least one of the cavities.

4. The method of claim 1, wherein in (b), at least one of the cavities includes at least one alignment opening disposed adjacent to at least one corner of the at least one of the cavities; wherein in (c), the electronic components are placed in the cavities through aligning with the alignment opening of the at least one of the cavities.

5. The method of claim 1, wherein (c) comprises:
(c1) using the mass transfer device to pick up the electronic components from the source carrier;
(c2) moving the mass transfer device to the buffer carrier; and
(c3) releasing suction forces from the mass transfer device to the electronic components after the mass transfer device contacting the upper surface of the buffer carrier to enable the electronic components to fall into the cavities of the buffer carrier.

6. The method of claim 5, wherein in (c1), the mass transfer device includes a plurality of suction pads, at least one of the suction pads has a surface and defines an accommodating cavity recessed from the surface, and the electronic component is sucked into the accommodating cavity.

7. (canceled)

8. A mass transfer device, comprising:
a plurality of suction pads spaced apart from each other, wherein at least one of the suction pads has a surface, and includes an accommodating cavity recessed from the surface; and
a buffer carrier, including:
a main body having an upper surface; and
a plurality of adjusting cavities recessed from the upper surface of the main body and configured to adjust a plurality of electronic components in the adjusting cavities from shifted positions to correct positions.

9. The device of claim 8, further comprising a base and a plurality of suction pins connected to the base and corresponding to the suction pads, the base includes a plurality of through holes extending through the base, one of the suction pins is disposed in one of the through holes of the base, one of the suction pads is connected to the corresponding one of the suction pins, a portion of at least one of the suction pins protrudes from a bottom surface of the base, and the suction pad is connected to the protruded portion of the at least one of the suction pins.

10. The device of claim 9, wherein at least one of the suction pads defines at least one through hole extending through the suction pad, and a portion of the protruded portion of the at least one of the suction pins is disposed in the through hole of the at least one of the suction pads.

11. The device of claim 10, wherein the accommodating cavity of the suction pad is in communication with the through hole of the suction pad.

12. (canceled)

13. A buffer carrier, comprising:
a main body having an upper surface, wherein a material of the main body is antistatic;
a plurality of adjusting cavities recessed from the upper surface of the main body, wherein at least one of the adjusting cavities has an inner adjusting sidewall below the upper surface of the main body,
wherein the at least one of the adjusting cavities includes an upper opening recessed from the upper surface of the main body and a lower opening below the upper opening, and a depth of the upper opening is greater than a depth of the lower opening; and
a coating covering the inner adjusting sidewall.

14. The buffer carrier of claim 13, wherein a surface of the coating is smoother than a surface of the inner adjusting sidewall.

15. (canceled)

16. The buffer carrier of claim 15, wherein the upper opening has an inclined sidewall, the lower opening has a vertical sidewall, and the inclined sidewall of the upper opening and the vertical sidewall of the lower opening constitute the inner adjusting sidewall.

17. The buffer carrier of claim 16, wherein an included angle is between the inclined sidewall of the upper opening and the vertical sidewall of the lower opening, and the included angle is 160° to 170°.

18. The buffer carrier of claim 15, wherein the at least one of the adjusting cavities further includes at least one alignment opening disposed adjacent to at least one corner of the at least one of the adjusting cavities.

19. (canceled)

20. (canceled)

21. (canceled)

22. (canceled)

23. (canceled)

24. The method of claim 1, wherein in (a), the at least two electronic components have different shifted positions.

25. The method of claim 24, wherein in (c), the at least two electronic components with different shifted positions are placed in the cavities of the buffer carrier to adjust positions of the at least two electronic components.

26. The method of claim 1, wherein in (d), the mass transfer device picks up the electronic components after the mass transfer device contacting the upper surface of the buffer carrier.

27. The method of claim 1, wherein in (d), the electronic components are attached to the receiving carrier through an adhesion layer.

28. The device of claim 8, wherein a material of the main body is antistatic.

29. The device of claim 8, wherein at least one of the adjusting cavities has an inner adjusting sidewall below the upper surface of the main body, and the at least one of the adjusting cavities includes an upper opening recessed from the upper surface of the main body and a lower opening below the upper opening, wherein the upper opening has a minimum width adjacent to the lower opening, and a width of the accommodating cavity is greater than the minimum width of the upper opening.

30. The device of claim 29, wherein a sum of a depth of the upper opening and a depth of the lower opening is greater than a depth of the accommodating cavity of the suction pad.

31. The device of claim 29, wherein the upper opening has a maximum width adjacent to the upper surface of the main body, and the maximum width of the upper opening is greater than the width of the accommodating cavity.
